(19) United States
(12) Patent Application Publication
(10) Pub. No.: US 2017/0092666 A1
(43) Pub. Date: Mar. 30, 2017

(54) THIN FILM TRANSISTOR ARRAY PANEL AND METHOD OF MANUFACTURING THE SAME

(71) Applicant: Samsung Display Co., Ltd., Yongin-si (KR)

(72) Inventors: Doo Youl LEE, Seoul (KR); Chang Jung KIM, Yongin-si (KR)

(21) Appl. No.: 15/231,932

(22) Filed: Aug. 9, 2016

(30) Foreign Application Priority Data
Sep. 25, 2015 (KR) 10-2015-0136612

(51) Int. Cl. H01L 27/12

(52) U.S. Cl. CPC H01L 27/1288; H01L 27/1233; H01L 27/127; H01L 27/1225; H01L 29/7869

(57) ABSTRACT

A manufacturing method of a thin film transistor array panel invention includes forming a semiconductor layer on a substrate including a display area and a peripheral area, arranging a photo mask including a first portion and a second portion having different transmittances from each other, the first portion corresponding to the display area and the second portion corresponding to the peripheral area, and patterning the semiconductor layer to form a first semiconductor disposed in the display area and a second semiconductor disposed in the peripheral area by using the photo mask, in which a thickness of the first semiconductor and a thickness of the second semiconductor are different from each other.

### CROSS-REFERENCE TO RELATED APPLICATION

This application claims priority from and the benefit of Korean Patent Application No. 10-2015-0136612, filed on Sep. 25, 2015, which is hereby incorporated by reference for all purposes as if fully set forth herein.

### BACKGROUND

Field

Exemplary embodiments relate to a thin film transistor array panel and a manufacturing method thereof, and, more particularly, to a thin film transistor array panel having improved characteristics and a manufacturing method thereof.

Discussion of the Background

Flat panel displays, such as a liquid crystal display (LCD), an organic light emitting diode (OLED) display, an electrophoretic display, and a plasma display, may include pairs of field generating electrodes and electro-optical active layers disposed therebetween. An LCD includes a liquid crystal layer as the electro-optical active layer, and an OLED display includes an organic emission layer as the electro-optical active layer. One of field generating electrodes may be connected to a switching element, to receive an electric signal, and the electro-optical active layer may convert the electric signal into an optical signal, to display an image.

A display panel with a thin-film transistor may be included in the flat panel display. Electrodes of many layers, a semiconductor, and the like may be patterned on the thin film transistor array panel, and a photo mask is generally used during the patterning process.

A semiconductor may be an important factor in determining the characteristics of the thin-film transistor. When amorphous silicon is used as the semiconductor material, it may be difficult to manufacture a high-performance thin-film transistor due to low charge mobility. When polysilicon is used as the semiconductor material, although a high-performance thin-film transistor may be manufactured due to high charge mobility, it may be difficult to manufacture a large-sized thin film transistor array panel, due to high cost and low uniformity.

Accordingly, research has been conducted for a thin-film transistor using an oxide semiconductor, which has a higher electron mobility and a higher current ON/OFF rate than those of amorphous silicon based thin-film transistor, and has a lower cost and higher uniformity than those of polysilicon based thin-film transistor.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide a thin film transistor array panel including an oxide semiconductor with different thicknesses for each panel region by controlling a photo mask transmittance, and a manufacturing method thereof.

Additional aspects will be set forth in the detailed description which follows, and, in part, will be apparent from the disclosure, or may be learned by practice of the inventive concept.

According to exemplary embodiments, a manufacturing method of a thin film transistor array panel invention includes forming a semiconductor layer on a substrate including a display area and a peripheral area, arranging a photo mask including a first portion and a second portion having different transmittances from each other, the first portion corresponding to the display area and the second portion corresponding to the peripheral area, and patterning the semiconductor layer to form a first semiconductor disposed in the display area and a second semiconductor disposed in the peripheral area by using the photo mask, in which a thickness of the first semiconductor and a thickness of the second semiconductor are different from each other.

According to exemplary embodiments, a thin film transistor array panel includes a substrate including a display area and a peripheral area, and a first semiconductor disposed in the display area and a second semiconductor disposed in the peripheral area, the first semiconductor and the second semiconductor including an oxide semiconductor, in which a first portion of the first semiconductor has a first thickness and a second portion of the second semiconductor has a second thickness different from the first thickness.

According to exemplary embodiments, oxide semiconductors disposed in a display area and a peripheral area may be formed to have different thicknesses from each other, by controlling the transmittance of each region of a photo mask, which may lower a distribution of a threshold voltage Vth of a thin-film transistor disposed in the display area and prevent degradation of a thin-film transistor disposed in the peripheral area.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a block diagram of a thin-film transistor array panel according to an exemplary embodiment of the present invention.

FIG. 2 is a top plan view illustrating a thin-film transistor array panel disposed in a display area of FIG. 1.

FIG. 3 is a cross-sectional view taken along line III-III′ of FIG. 2.

FIG. 4 is a layout view showing a driving transistor of a driver among the thin-film transistor array panel disposed in peripheral area PA of FIG. 1.

FIG. 5 is a cross-sectional view taken along line V-V′ of FIG. 4.

FIG. 6, FIG. 7, FIG. 8, FIG. 9, FIG. 10, FIG. 11, and FIG. 12 are cross-sectional views illustrating a manufacturing method of a thin-film transistor array panel according to an exemplary embodiment of the present invention.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

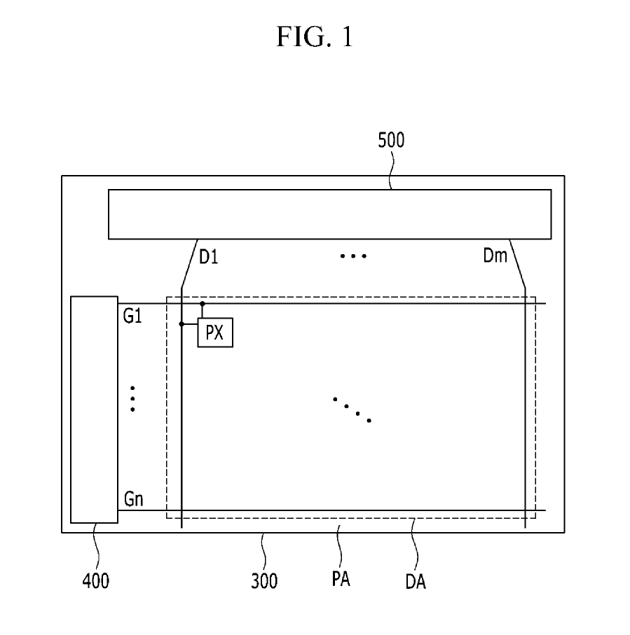

A display area DA of a thin film transistor array panel according to an exemplary embodiment of the present invention will be described with reference to FIG. 1 to FIG. 3.

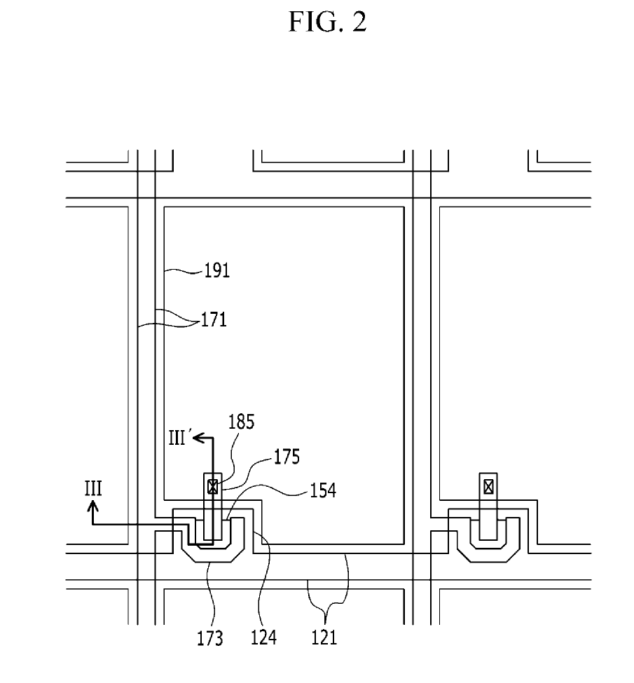

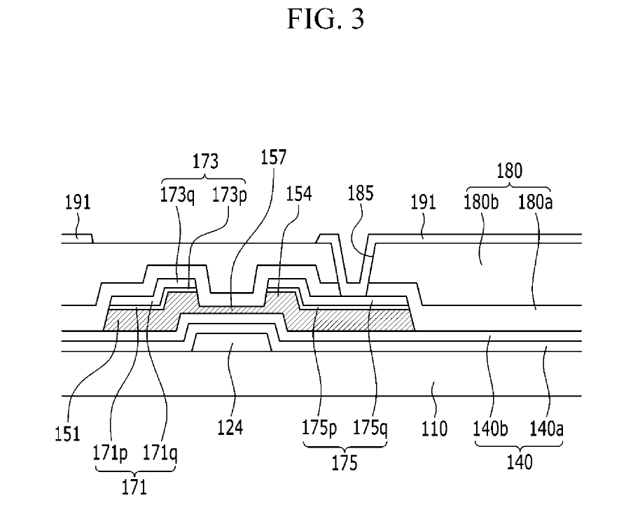

FIG. 1 is a block diagram of a thin film transistor array panel according to an exemplary embodiment of the present invention. FIG. 2 is a top plan view illustrating a thin film transistor array panel disposed in a display area of FIG. 1. FIG. 3 is a cross-sectional view taken along line III-III′ of FIG. 2.

Referring to FIG. 1, the thin film transistor array panel according to an exemplary embodiment of the present invention includes a display panel 300, a gate driver 400, and a data driver 500.

The display panel 300 includes gate lines G1 to Gn, data lines D1 to Dm, and pixels PXs connected to the gate lines G1 to Gn and the data lines D1 to Dm. The display panel 300 may include a display area DA, in which the pixels PX are arranged, and a peripheral area PA near the display area DA. The peripheral area PA may be a circumference region of the display panel 300 surrounding the display area DA. The gate lines G1-Gn may transmit a gate signal and the data lines D1-Dm may transmit a data voltage. Each pixel PX may include a switching element and a pixel electrode that are connected to one of the gate lines G1-Gn and one of the data lines D1-Dm. The switching element may be a three-terminal element, such as a thin-film transistor integrated in the display panel 300.

The data driver 500 is connected to the data lines D1-Dm to transmit the data voltage. The data driver 500 may be directly mounted in the peripheral area PA of the display panel 300, integrated directly in the peripheral area PA in the same manufacturing process as the switching element including the pixel PX, or disposed on a flexible printed circuit film attached to the display panel 300.

The scan driver 400 is integrated in the peripheral area PA of the display panel 300, and may sequentially transmit the gate signal to the gate lines G1-Gn. The gate signal includes a gate-on voltage Von and a gate-off voltage Voff. The gate driver 400 may receive a scanning start signal instructing an output start of a gate-on pulse, to sequentially drive gate lines G1-Gn, and a gate clock signal controlling an output timing of a gate-on pulse. The signal lines that may transmit the scanning start signal and the gate clock signal to the gate driver 400 may be disposed in the peripheral area PA of the display panel 300.

Various constituent elements besides the display panel 300, the scan driver 400, and the data driver 500 included in the display device may include electrical elements, such as transistors, capacitors, and diodes.

Referring to FIG. 2 and FIG. 3, the thin film transistor array panel according to the present exemplary embodiment is disposed in the display area DA and includes gate lines 121 disposed on the substrate 110 made of transparent glass or plastic.

The gate lines 121 may transmit a gate signal and mainly extend in a transverse direction. Each gate line 121 includes a first gate electrode 124 that protrudes from the gate line 121.

The gate lines 121 and the first gate electrode 124 may include an aluminum-based metal, such as aluminum (Al) and an aluminum alloy, a silver-based metal, such as silver (Ag) and a silver alloy, a copper-based metal, such as copper (Cu) and a copper alloy, a molybdenum-based metal, such as molybdenum (Mo) and a molybdenum alloy, chromium (Cr), titanium (Ti), tantalum (Ta), manganese (Mn), or the like. In the present exemplary embodiment, the gate lines 121 and the first gate electrode 124 have a single layer. Alternatively, the gate lines 121 and the first gate electrode 124 may have a dual layer or multiple layers.

A gate insulating layer 140 including an insulating material, such as silicon oxide or silicon nitride is disposed on the gate lines 121. The gate insulating layer 140 may include a first insulating layer 140a and a second insulating layer 140b. The first insulating layer 140a may include silicon nitride (SiNₓ) with a thickness of about 4000 Å, and the second insulating layer may include silicon oxide (SiOₓ) with a thickness of about 500 Å. According to an exemplary embodiment of the present invention, the first insulating layer 140a may include silicon oxynitride (SiON), and the second insulating layer 140b may include silicon oxide (SiOₓ). In the present exemplary embodiment, the gate insulating layers 140a and 140b have a dual layer. Alternatively, the gate insulating layer 140 may have a single layer.

A first semiconductor 151 is disposed on the gate insulating layer 140. The first semiconductor 151 may include amorphous silicon, crystalline silicon, or an oxide semiconductor. The first semiconductor 151 may include a portion mainly extending in a longitudinal direction and projections 154 extending toward the gate electrode 124. Alternatively, the portion extending in the longitudinal direction in the first semiconductor 151 may be omitted.

When the first semiconductor 151 is formed as an oxide semiconductor, the first semiconductor 151 may include at least one of zinc (Zn), indium (In), tin (Sn), gallium (Ga), and hafnium (Hf). In particular, in the present exemplary embodiment, the first semiconductor 151 may be indium-gallium-zinc oxide (IGZO).

A data wire layer including the data lines 171, the source electrodes 173 connected to the data lines 171, and the drain electrodes 175 are disposed on the first semiconductor 151 and the gate insulating layer 140. The data lines 171 may transfer data signals and extend substantially in the longitudinal direction to cross the gate lines 121. The first source electrode 173 may extend from the data lines 171 and overlap the first gate electrode 124, and may substantially have a “U” shape. The first drain electrode 175 is separated from the data lines 171 and extends upward from the center of the “U” shape of the first source electrode 173.

The data lines 171, the first source electrode 173, and the first drain electrode 175 have a dual-film structure of a barrier layer (171p, 173p, or 175p) and a main wiring layer (171q, 173q, or 175q). The barrier layers 171p, 173p, and 175p may include a metal oxide and the main wiring layers 171q, 173q, and 175q may include copper or copper alloy. In detail, the barrier layers 171p, 173p, and 175p may include one of an indium-zinc oxide (IZO), a gallium-zinc oxide (GZO), and an aluminum-zinc oxide (AZO).

The barrier layers 171p, 173p, and 175p may serve as a diffusion-preventing layer, which may prevent material such as copper or the like from being diffused to the first semiconductor 151. Alternatively, the data lines 171, the first source electrode 173, and the first drain electrode 175 may include a single layer or multiple layers of different metals.

Referring to FIG. 3, the projection 154 of the first semiconductor 151 includes an exposed portion 157 of the first semiconductor 151 that is not covered by the data lines 171, and a portion of the data line 171 between the first source electrode 173 and the first drain electrode 175. The exposed portion 157, which corresponds to an exposed portion of the first semiconductor 151 between the first source electrode 173 and the first drain electrode 175, is relatively thinly formed in the thickness direction of the thin film transistor array panel, as compared with the first semiconductor 151 and projection 154 that are not exposed. Hereinafter, the thickness of a semiconductor layer will be described with reference to the thickness direction of the thin film transistor array panel.

The first semiconductor 151 may have substantially the same plane pattern as the data line 171 and the first drain electrode 175, except for the exposed portion 157. In other words, edge portions of the first semiconductor 151 may substantially accord with edge portions of the data lines 171 and first drain electrode 175.

One first gate electrode 124, one first source electrode 173, and one first drain electrode 175 form one thin-film transistor (TFT) along with the projection 154 of the first semiconductor 151. The channel of the thin-film transistor is formed in the exposed portion 157 between the first source electrode 173 and the first drain electrode 175.

A passivation layer 180 is disposed on the main wiring layers 171q, 173q, and 175q. The passivation layer 180 includes an inorganic insulator, such as a silicon nitride or a silicon oxide, an organic insulator, or a low-dielectric insulator.

In the present exemplary embodiment, the passivation layer 180 includes a lower passivation layer 180a and an upper passivation layer 180b. The lower passivation layer 180a may include silicon oxide, and the upper passivation layer 180b may include silicon nitride. According to the present exemplary embodiment, since the first semiconductor 151 includes the oxide semiconductor, the lower passivation layer 180a adjacent to the first semiconductor 151 includes silicon oxide. In this case, if the lower passivation layer 180a includes silicon nitride, characteristics of the thin-film transistor may be degraded.

The passivation layer 180 may contact the exposed portion 157 that is not covered by the first source electrode 173 and the first drain electrode 175 between the first source electrode 173 and the first drain electrode 175. The passivation layer 180 includes contact holes 185 exposing one end of the first drain electrode 175.

Pixel electrodes 191 are disposed on the passivation layer 180. The pixel electrode 191 is physically and electrically connected to the first drain electrode 175 through the contact hole 185, thereby receiving the data voltage from the first drain electrode 175. The pixel electrode 191 may be formed of a transparent conductor such as indium tin oxide (ITO) or indium zinc oxide (IZO).

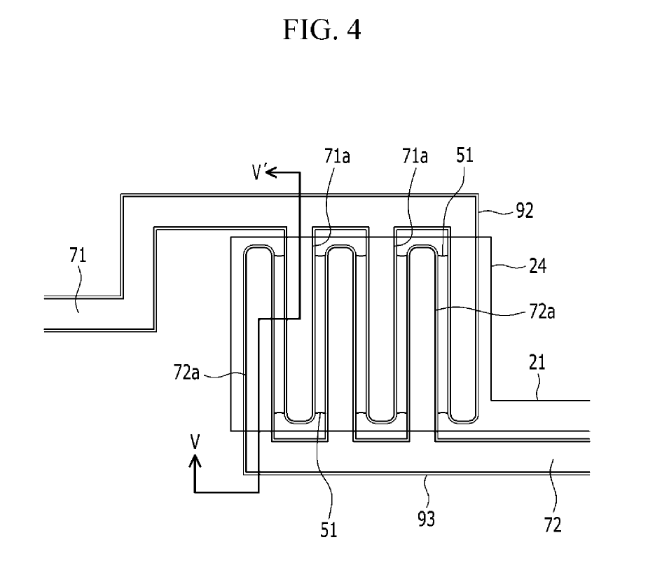

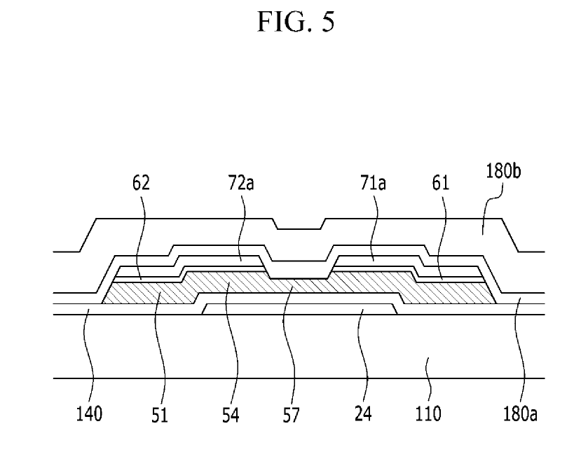

A peripheral area PA of the thin film transistor array panel according to an exemplary embodiment of the present invention will be described with reference to FIG. 1, FIG. 4, and FIG. 5.

FIG. 4 is a layout view showing a driving transistor of a driver among the thin film transistor array panel disposed in peripheral area PA of FIG. 1. FIG. 5 is a cross-sectional view taken along line V-V′ of FIG. 4. FIG. 4 illustrates the driving transistor of the gate driver 400 of FIG. 1.

Referring to FIG. 4 and FIG. 5, a driving control signal line 21 is disposed on the substrate 110. The driving control signal line 21 includes a driving control electrode 24 corresponding to a second gate electrode. The driving control signal line 21 and the gate line 121 may be formed simultaneously on the same layer.

A gate insulating layer 140 is disposed on the driving control signal line 21 and the driving control electrode 24. A second semiconductor 51 is disposed on the gate insulating layer 140. The second semiconductor 51 may include amorphous silicon, crystalline silicon, or oxide semiconductor. The second semiconductor 51 may include the same material as the first semiconductor 151. When the second semiconductor 51 is formed of the oxide semiconductor, the second semiconductor 51 may include at least one of zinc (Zn), indium (In), tin (Sn), gallium (Ga), and hafnium (Hf). According to the present exemplary embodiment, the second semiconductor 51 may include indium-gallium-zinc oxide (IGZO).

A third barrier layer 61 and a fourth barrier layer 62 are disposed on the second semiconductor 51. A driving input signal line 71 including a driving input electrode 71a, which may correspond to a second source electrode, and a driving output signal line 72 including a driving output electrode 72a, which may correspond to a second drain electrode, are disposed on the third barrier layer 61 and the fourth barrier layer 62, respectively. The driving input signal line 71 including the driving input electrode 71a and the driving output signal line 72 including the driving output electrode 72a may be formed simultaneously on the same layer as the data line 171 and the first drain electrode 175.

The lower passivation layer 180a and the upper passivation layer 180b are sequentially disposed on the driving input electrode 71a and the driving output electrode 72a. In this case, a projection 54 of the second semiconductor 51 includes an exposed portion 57 that is not covered by the driving input electrode 71a and the driving output electrode 72a of the second semiconductor 51. A thickness of the exposed portion 57 of the second semiconductor 51 may be relatively less than a thickness of the second semiconductor 51 and the projection 54 that are not exposed, in the thickness direction of the thin film transistor array panel.

According to the present exemplary embodiment, the second semiconductor 51 of the thin-film transistor formed in the gate driver 400, which is disposed in the peripheral area PA, may be formed to have the same thickness as the first semiconductor 154 of the thin-film transistor formed in the display area DA. However, the exposed portion 57 of the second semiconductor 51, in which a channel of the thin-film transistor disposed in the peripheral area PA is formed, may have a greater thickness than a thickness of the exposed portion 157 of the first semiconductor 151, in which a channel on the thin-film transistor disposed in the display area DA is formed.

In a thin-film transistor disposed in the gate driver 400, when the voltage between the source electrode and the drain electrode is high, for example, at about 60V, the thin-film transistor may be degraded. On the other hand, a thin-film transistor disposed in the display area DA may function as a switch element. As such, if the thickness of the thin-film transistor in the display area DA is increased, the value of the threshold voltage Vth in the initial characteristic may be negatively shifted, which may render a control of a threshold voltage distribution difficult. In other words, a thickness of a semiconductor may be different, depending on a region of the thin film transistor array panel.

According to the present exemplary embodiment, a thickness of a semiconductor, which corresponds to a channel region of a thin-film transistor disposed in the gate driver 400, is formed to be greater than a thickness of a semiconductor that corresponds to a channel region of a thin-film transistor in the display area DA, thereby lowering the magnitude of electric field applied thereto. In addition, a thickness of a semiconductor disposed in a wiring region, in which a wiring such as the source electrode and the drain electrode are formed, is formed to be greater than a thickness of a semiconductor disposed in a channel forming area. In this manner, as the semiconductor thickness of the thin-film transistor disposed in the display area DA is less than the semiconductor thickness of the thin-film transistor of the gate driver 400, the threshold voltage distribution may be reduced.

The first semiconductor 151, the second semiconductor 51, and the channel regions 157 and 57 of the first and second semiconductor 151 and 51 may be formed by using one photo mask through a transmittance control.

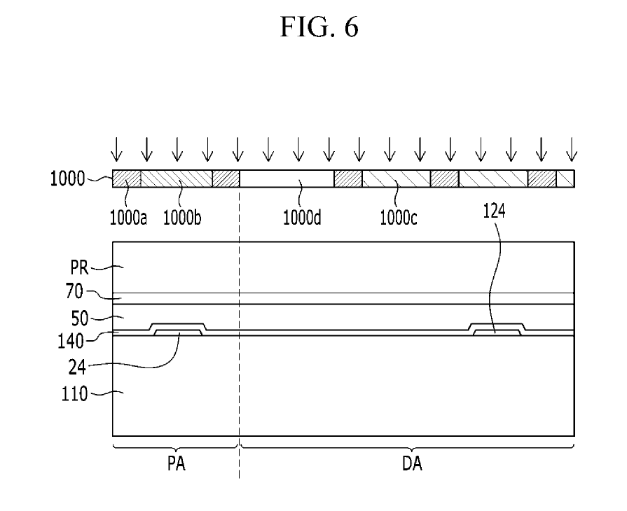

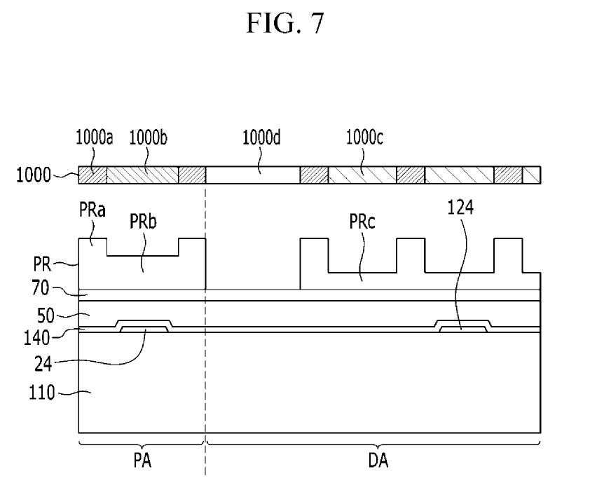

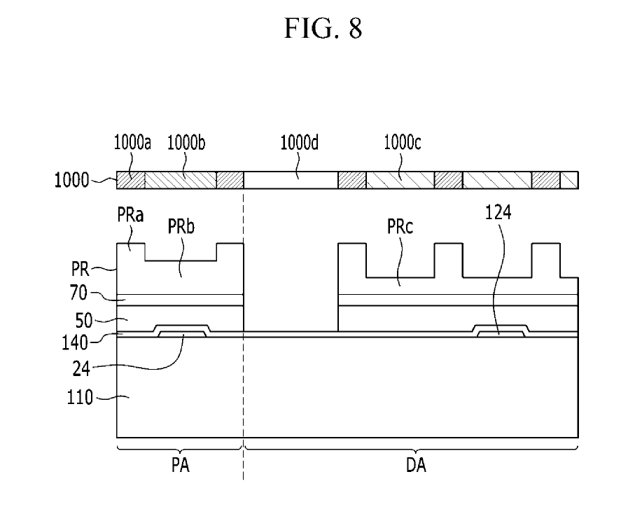

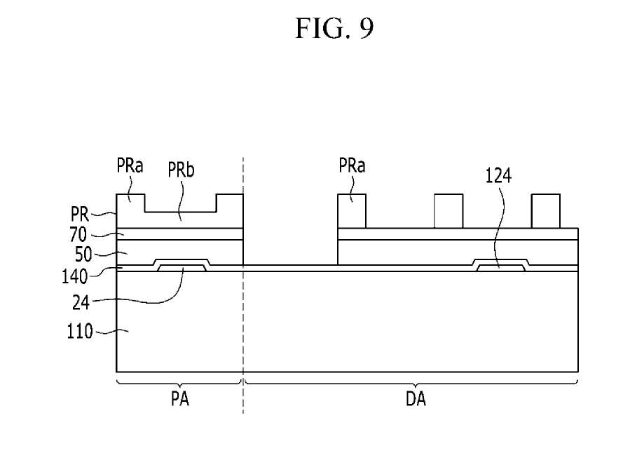

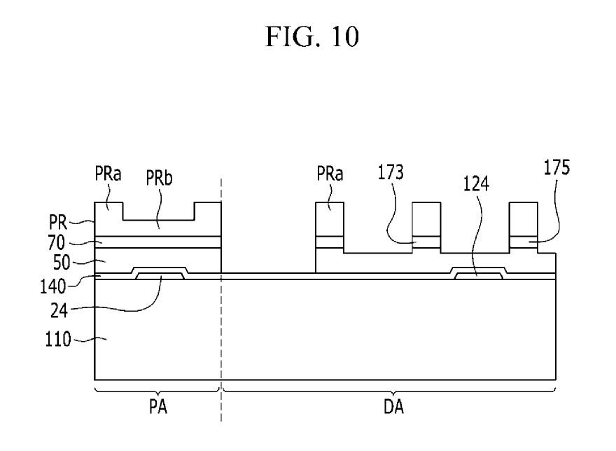

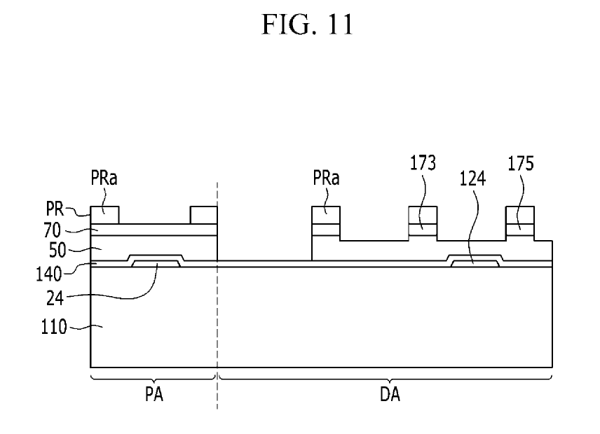

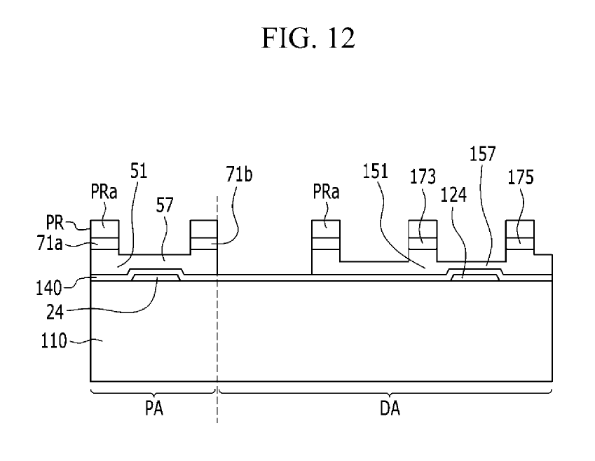

A manufacturing method of the thin film transistor array panel according to an exemplary embodiment of the present invention will be described with reference to FIG. 6 to FIG. 12

FIG. 6 to FIG. 12 are cross-sectional views showing a manufacturing method of a thin film transistor array panel according to an exemplary embodiment of the present invention.

Referring back to FIG. 1 to FIG. 5, first the gate line 121, the first gate electrode 124, the driving control signal line 21, and the driving control electrode 24 are disposed on the substrate 110. The gate insulating layer 140 is formed thereon.

FIG. 6 schematically shows a structure including the gate electrode 124, the driving control electrode 24, and the gate insulating layer 140 disposed on the substrate 110. An oxide semiconductor 50, a data metal layer 70, and a photosensitive film PR are sequentially disposed on the gate insulating layer 140. For descriptive convenience, in FIGS. 6 to 12, detail description of other constituent elements of the thin film transistor array panel will be omitted in order to avoid obscuring exemplary embodiments described herein.

Referring to FIG. 6, a photo mask 1000 is arranged on the substrate 110, on which the oxide semiconductor 50, the data metal layer 70, and the photosensitive film PR are sequentially disposed. In this case, the photo mask 1000 may cover both the display area DA and the peripheral area PA of the substrate 110.

The photo mask 1000 according to the present exemplary embodiment may include multiple regions having different transmittances from each other. For example, portions of the photo mask 1000 corresponding to each channel part may be configured to have a transmittance different from one another. In this manner, an etching degree of the photosensitive film corresponding to the channel part of the semiconductor of the display area DA may be different from that corresponding to the channel part of the semiconductor of the peripheral area PA. Accordingly, a first mask region 1000a corresponding to the source/drain wiring region, a second mask region 1000b corresponding to the channel part of the semiconductor of the peripheral area PA, a third mask region 1000c corresponding to the channel part of the semiconductor of the display area DA, and a fourth mask region 1000d corresponding to the region in which the semiconductor is not formed, may have a different transmittance from one another.

For example, the first mask region 1000a may not transmit light, and, thus, the transmittance thereof may be nearly 0%. The fourth mask region 1000d may substantially transmit light, and, thus, the transmittance thereof may be nearly 100%. The second mask region 1000b has a lower transmittance than the third mask region 1000c.

In this manner, when an exposure process of irradiating light on the photo mask 1000 having different transmittances on each region, an etched degree of the photosensitive film PR may be different according to the transmittance of corresponding first mask region to fourth mask region 1000a to 1000d. Accordingly, a photosensitive film pattern as shown in FIG. 7 may be formed.

Referring to FIG. 7, the photosensitive film pattern formed via the exposure process is etched to have a different thickness, which corresponds to the first, second, third, and fourth mask regions 1000a, 1000b, 1000c, and 1000d of the photo mask 1000. In this manner, the photosensitive film pattern may include a first photosensitive film region PRa, a second photosensitive film region PRb, and a third photosensitive film region PRc, and a region where the photosensitive film PR is substantially etched is formed. For example, etching the photosensitive film PR corresponding to the fourth mask region 1000d, of which the transmittance thereof is nearly 100%, may partially expose a portion of the data metal layer 70 corresponding to the fourth mask region 1000d.

Referring to FIG. 8, a first etching process is performed on the data metal layer 70 and the semiconductor 50. In this case, a portion of the semiconductor layer 50 corresponding to the first photosensitive film region PRa, second photosensitive film region PRb, and the third photosensitive film region PRc may not be etched due to corresponding photosensitive film disposed thereon. A portion of the semiconductor layer 50 and the data metal layer 70 corresponding to the fourth mask region 1000d are etched. The first etching process is performed until the gate insulating layer 140 corresponding to the fourth mask region 1000d is exposed. In this case, although not shown in FIG. 8, the wiring may be performed in the region where the gate insulating layer 140 is exposed.

Referring to FIG. 9, a first etch back process is performed on the photosensitive film PR formed throughout the display area DA and the peripheral area PA. The first etch back process is performed until the data metal layer 70 corresponding to the channel part in the display area DA is exposed. In this manner, the third photosensitive film region PRc is totally removed. Since the thickness of the third photosensitive film region PRc and the second photosensitive film region PRb are different from one another, a portion of the second photosensitive film region PRb may exist after the first etch back process. Accordingly the data metal layer 70 corresponding to the second photosensitive film region PRb may not be exposed from the first etch back process.

Referring to FIG. 10, a second etching process etching the data metal layer 70 and the semiconductor layer 50 is performed, by using the photosensitive film PR of FIG. 9 as an etching mask. Through the second etching process, the data metal layer 70 and the semiconductor layer 50 that are not covered by the photosensitive film PR in the display area DA are etched to a first thickness. A portion of the data metal layer 70 corresponding to the channel part of the display area DA is removed through the second etching process, and a portion of the semiconductor layer 50 disposed thereunder may be removed to a second thickness. In this manner, the data metal layer 70 in the display area DA forms the wiring region including the source electrode 173 and the drain electrode 175, through the second etching process.

Referring to FIG. 11, a second etch back process is performed on the remaining photosensitive film PR throughout the display area DA and the peripheral area PA. In this case, the second etch back process is performed until the second photosensitive film PRb is entirely removed, such that the data metal layer 70 corresponding to the channel part is exposed in the peripheral area PA.

Referring to FIG. 12, a third etching process etching the data metal layer 70 exposed in the peripheral area PA is performed. In this case, the etching process is performed until the data metal layer 70 is removed and the semiconductor layer 50 disposed thereunder is partially removed. Through the third etching process, the driving output signal line 72 including the driving input electrode 71a and the driving output electrode 72a, which corresponds to the gate driver 400, may be formed along with the semiconductor layer 50 corresponding to the channel part 57 of the peripheral area PA. In this case, the semiconductor layer 50 exposed in the display area DA may also be etched during the third etching process.

Accordingly, the thickness of the semiconductor layer 50 corresponding to the channel part of the display area DA may become thinner. Accordingly, the thickness of the semiconductor 157 corresponding to the channel part of the display area DA may be less than the thickness of the semiconductor 57 corresponding to the channel part of the peripheral area PA. Since a portion of the semiconductor layer 50 (or 51 and 151) covered by the first photosensitive film PR are not etched, the thickness of thereof may be relatively greater that the thickness of the semiconductors 57 and 157 of the channel part of the peripheral area PA and the display area DA.

Although not illustrated, the lower passivation layer 180a and the upper passivation layer 180b may be sequentially disposed throughout the display area DA and the peripheral area PA to form the thin film transistor array panel.

According to exemplary embodiment of the present invention illustrated with reference to FIG. 6 to FIG. 12, the semiconductor layer 50 is disposed on the substrate 110 to have the same thickness in the display area DA and the peripheral area PA. Utilizing the photo mask 1000 that has different transmittances for the channel parts in the display area DA and the peripheral area PA, the thicknesses of a semiconductor for each region may be variously formed in the thickness direction of the thin film transistor array panel. Accordingly, the thickness of the exposed portion 157 of the first semiconductor 151 disposed in the display area DA may be formed to be less than the exposed portion 57 of the second semiconductor 51 disposed in the peripheral area PA. The semiconductor 151 and 51 of the wiring region including the source/drain electrode disposed in the display area DA and the peripheral area PA may be formed to be relatively thicker than the semiconductors 157 and 57 formed in the channel part. In this manner, the semiconductor 151 and 51 of the wiring region may have the a first thickness, the semiconductor 157 forming the channel part of the display area DA may have a second thickness less than the first thickness. Accordingly, the channel part semiconductor of the peripheral area PA and the channel part semiconductor of the display area DA may be formed to have a different thickness from one another.

Although certain exemplary embodiments and implementations have been described herein, other embodiments and modifications will be apparent from this description. Accordingly, the inventive concept is not limited to such exemplary embodiments, but rather to the broader scope of the presented claims and various obvious modifications and equivalent arrangements.

What is claimed is:

1. A method for manufacturing a thin film transistor array panel, the method comprising:
forming a semiconductor layer on a substrate, the substrate comprising a display area and a peripheral area;
arranging a photo mask, the photo mask comprising a first portion and a second portion having different transmittances from each other, the first portion corresponding to the display area and the second portion corresponding to the peripheral area; and
patterning the semiconductor layer to form a first semiconductor disposed in the display area and a second semiconductor disposed in the peripheral area by using the photo mask,
wherein a thickness of the first semiconductor and a thickness of the second semiconductor are different from each other.

2. The method of claim 1, wherein:
the photo mask further comprises:
a first mask region corresponding to a first channel part of the first semiconductor;
a second mask region corresponding to a second channel part of the second semiconductor; and
a third mask region corresponding to a wiring part of the display area and the peripheral area; and
transmittances of the first mask region, the second mask region, and the third mask region are different from each other.

3. The method of claim 2, wherein the transmittance of the second mask region is higher than the transmittance of the first mask region.

4. The method of claim 3, wherein the transmittance of the third mask region is higher than the transmittance of the second mask region.

5. The method of claim 4, further comprising:
forming a data metal layer on the semiconductor layer; and
forming a photosensitive film on the data metal layer.

6. The method of claim 5, wherein forming the first semiconductor and the second semiconductor comprises removing a portion of the photosensitive film corresponding to the first and second channel parts by using the photo mask, to form a photosensitive film pattern.

7. The method of claim 6, wherein removing the portion of the photosensitive film does not expose the data metal layer corresponding to the first and second channel parts.

8. The method of claim 7, wherein forming the first semiconductor and the second semiconductor further comprises:
performing a first etch-back on the photosensitive film pattern; and
performing a first etching on the data metal layer and the semiconductor layer by using the first etch-backed photosensitive film pattern as an etching mask.

9. The method of claim 8, wherein:
the first etch-back comprises partially removing the photosensitive film to expose a first portion of the data metal layer disposed on a first portion of the semiconductor layer corresponding to the first channel part; and
the first etching comprises removing the first portion of the data metal layer and partially etching the first portion of the semiconductor layer.

10. The method of claim 9, wherein forming the first semiconductor and the second semiconductor further comprises:
performing a second etch-back on the photosensitive film pattern; and
performing a second etching on the data metal layer and the semiconductor layer by using the second etch-backed photosensitive film pattern as an etching mask.

11. The method of claim 10, wherein:
the second etch-back comprises partially removing the photosensitive film to expose a second portion of the data metal layer disposed on a second portion of the semiconductor layer corresponding to the second channel part; and
the second etching comprises removing the second portion of the data metal layer and partially etching the second portion of the semiconductor layer.

12. The method of claim 11, wherein the second portion of the semiconductor layer is etched to have a first thickness by the second etching.

13. The method of claim 12, wherein the first semiconductor and the second semiconductor comprise an oxide semiconductor, the oxide semiconductor comprising at least one of indium, gallium, and zinc.

14. A thin film transistor array panel, comprising:
a substrate comprising a display area and a peripheral area; and
a first semiconductor disposed in the display area and a second semiconductor disposed in the peripheral area, the first semiconductor and the second semiconductor comprising an oxide semiconductor,
wherein a first portion of the first semiconductor has a first thickness and a second portion of the second semiconductor has a second thickness different from the first thickness.

15. The thin film transistor array panel of claim 14, wherein the first portion corresponds to a first channel part of a first thin-film transistor and the second portion corresponds to a second channel part of a second thin-film transistor.

16. The thin film transistor array panel of claim 15, wherein the first thickness is less than the second thickness.

17. The thin film transistor array panel of claim 16, wherein a third thickness corresponding to a wiring part of the first or second semiconductor is greater than the second thickness.

18. The thin film transistor array panel of claim 16, wherein the oxide semiconductor comprises at least one of among indium, gallium, and zinc.
